(19) United States
(12) Patent Application Publication
(10) Pub. No.: US 2017/0221701 A1
(43) Pub. Date: Aug. 3, 2017

(54) RTP PROCESS FOR DIRECTED SELF-ALIGNED PATTERNS

(71) Applicant: Applied Materials, Inc., Santa Clara, CA (US)

(72) Inventors: Aaron Muir HUNTER, Santa Cruz, CA (US); Kong Lung Samuel CHAN, Newark, CA (US); Christine Y. OUYANG, Santa Clara, CA (US); Ludovic GODET, Sunnyvale, CA (US)

(21) Appl. No.: 15/422,116

(22) Filed: Feb. 1, 2017

Related U.S. Application Data
(60) Provisional application No. 62/289,788, filed on Feb. 1, 2016.

(51) Int. Cl. H01L 21/027; H01L 21/687; H01L 21/67; H01L 21/3105; H01L 21/324

(52) U.S. Cl. CPC H01L 21/0271; H01L 21/31058; H01L 21/324; H01L 21/67115; H01L 21/68764

(57) ABSTRACT

A semiconductor processing method and semiconductor device are described. A substrate having a directed self-assembling material disposed thereon is heated to a temperature above the glass transition temperature of the directed self-assembling material, for example from about 325° C. to 380° C., in an RTP process. The substrate is then cooled at a controlled rate of less than 5° C./sec to 100° C. or lower.

### CROSS-REFERENCE TO RELATED APPLICATIONS

This application claims benefit of U.S. Provisional Patent Application Ser. No. 62/289,788 filed Feb. 1, 2016, which is incorporated by reference herein.

### FIELD

Embodiments of the present disclosure generally relate to patterning processes used to manufacture semiconductor devices.

### BACKGROUND

Semiconductor manufacturers continue to search for ways to make smaller devices. Current mass production processes are capable of making devices having critical dimensions as small as 14 nm, while technology nodes at 10 nm, 7 nm, and still smaller are in development. Standard processes for patterning such devices rely on photolithography, which is limited by the wavelength of light used to expose photoresists. As devices become smaller, diffraction limits the size of features that can be resolved using UV light in the deep UV wavelength range below 193 nm. Still shorter wavelengths in the x-ray range do not chemically couple with photoresist materials to enable patterning.

Directed self-assembly of block copolymers has recently been investigated for the potential to enable sub-lithographic patterning. A material is applied to a substrate that may have a lithographic pattern, or a pattern directly written into the substrate using, for example, an electron beam apparatus. The material is then encouraged to separate into phases according to the substrate pattern. To date, however, it has proven difficult to find ways to achieve clean, regular patterns using directed self-assembly patterning. Therefore, new directed self-assembly patterning methods are needed.

### SUMMARY

Embodiments of the present disclosure provide a method of processing a semiconductor substrate, comprising heating a semiconductor substrate having a directed self-assembling material disposed thereon to a target temperature between about 325° C. and about 380° C., and cooling the substrate to a temperature of 100° C. at a rate less than about 5° C./sec.

Also disclosed is a method of patterning a substrate, comprising providing a substrate having a directed self-assembling material disposed thereon to an RTP chamber; heating the substrate at a rate of 5° C. or more to a target temperature of 325° C. to 380° C.; and cooling the substrate to a temperature of 100° C. at a controlled rate less than 5° C./sec.

Also disclosed is a method of processing a substrate, comprising forming a directed self-assembling material on a patterned substrate; at least partially drying the directed self-assembling material; heating the substrate in a uniform radiant energy field at a rate of 5° C. or more to a temperature above the glass transition temperature of the directed self-assembling material; and cooling the substrate at a controlled rate of 1° C. or less to a temperature of 100° C.

### BRIEF DESCRIPTION OF THE DRAWINGS

FIG. 1 is a flow diagram summarizing a method according to one embodiment.

FIG. 2A is a micrograph showing a substrate patterned according to one embodiment of the method 100.

FIG. 2B is a micrograph showing a substrate patterned according to another embodiment of the method 100.

FIG. 3A is a micrograph showing a patterned substrate after performing a comparative method.

FIG. 3B is a micrograph showing a patterned substrate after performing another comparative method.

### DETAILED DESCRIPTION

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a basis plane of the chamber, for example a plane parallel to a substrate processing surface of the chamber.

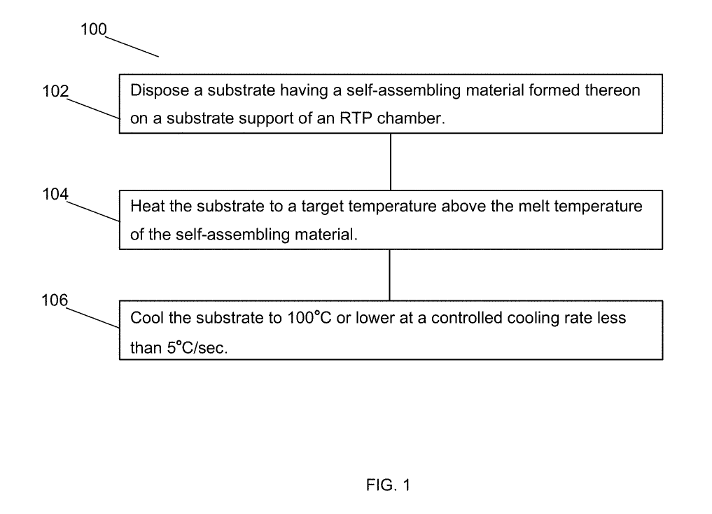

The inventors have discovered that a carefully calibrated RTP process can be used to form a sub-lithographic pattern on a substrate having a self-assembling material deposited thereon. FIG. 1 is a flow diagram summarizing a method 100 according to one embodiment. At 102, a substrate having a pattern formed thereon, and coated with a self-assembling material, is disposed on a substrate support in an RTP chamber. The RTP chamber is a radiant energy chamber that exposes the substrate to a uniform radiant energy field. Examples of such chambers include the RADIANCE® and VULCAN® chambers available from Applied Materials, Inc., of Santa Clara, Calif., as well as RTP chambers available from other manufacturers.

The self-assembling material is typically an amphiphilic block copolymer, such as a block polyolefin-polyacrylate copolymer. Polystyrene-polymethylmethacrylate (PS-b-PMMA) is a commonly used material, but any polymeric or oligomeric material having hydrophilic and hydrophobic portions may be used. The material is applied to the substrate using a layer forming method, such as a spin-on method. The self-assembling material is typically dissolved in a solvent, such as toluene or acetone, and spun-on to a thickness of 300 nm or less, for example about 100 nm. The substrate is then dried, for example by heating under vacuum, to remove the solvent. In this stage, the self-assembling material is mostly unstructured and randomly oriented.

At 104, the substrate is heated to a target temperature above the glass transition temperature, T_{g}, of the self-assembling material. The target temperature is usually sufficiently above the glass transition temperature to develop significant molecular mobility in the polymer, but is usually less than the midpoint between the glass transition temperature and the decomposition temperature, T_{c}. Limiting the temperature of the substrate in this way avoids subjecting the substrate to unwanted heat history. In some cases, the target temperature is above the crystalline melt temperature of the self-aligning material.

The processing temperature range is defined as ΔT_{P}=T_{c}−T_{g}, the target temperature is T=T_{g}+αΔT_{P}=(1+α)T_{g}−αT_{c}. The constant α is a thermal processing coefficient for the RTP process, and is usually from about 0.2 to about 0.5, for example about 0.3. In one embodiment, the target temperature is about 325° C. to about 380° C., such as about 330° C. to about 350° C., for example about 340° C. During the heating, the temperature of the substrate is raised at a rate of at least about 5° C./sec, for example about 10° C./sec.

In some cases, the self-aligning material exhibits a transition from an ordered structure to a disordered structure at a temperature below the decomposition temperature. With such materials, this temperature is commonly denoted T_{ODT}. In such cases, the target temperature T is typically greater than a midpoint temperature between T_{ODT} and T_{g}. If the target temperature is expressed in terms of T_{ODT} as T=(1+β)T_{g}−βT_{ODT}, the processing parameter β is typically from 0.5 to 0.95, for example about 0.9.

At 106, the substrate is cooled at a controlled rate less than about 5° C./sec. The power output of the RTP chamber is reduced below the radiant power output of the substrate and controlled to limit cooling to the controlled rate, which may be 1° C./sec or less in some cases. It is believed that the controlled cooling rate promotes organization of phases of the block copolymer by providing a heat history that advantageously matches the kinetics of phase separation in the self-assembling material. The substrate may be rotated during one or both of the heating and cooling operations, for example at a rate of 50-100 rpm. During operation 106, the substrate may be cooled to a temperature of 100° C. or lower.

The substrate may be maintained at the target temperature for a short bake duration in some embodiments. The bake duration is typically less than about 200 msec, such as less than about 100 msec, for example about 10 msec. The substrate dwell time at the target temperature may be controlled by adjusting the power output of the RTP chamber, taking into account the thermal properties of the chamber components and the substrate. To reduce dwell time at or above the target temperature, power may be reduced up to 100 msec before the substrate reaches the target temperature.

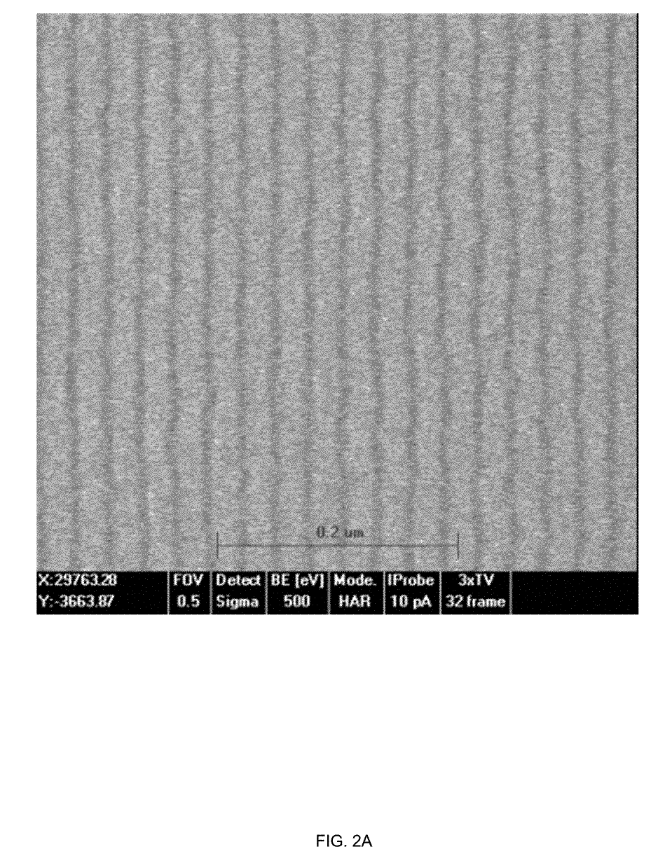

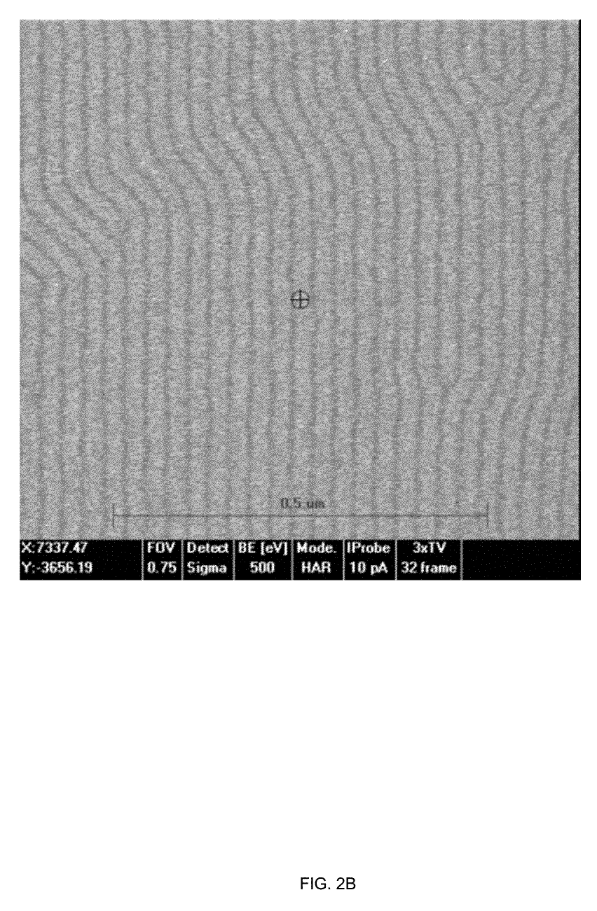

FIG. 2A is a micrograph of a substrate processed according to one embodiment of the method 100. To make the substrate of FIG. 2A, a patterned substrate was coated with a self-aligning material, dried, heated to 340° C., and cooled at a controlled rate of 1° C./sec. The substrate of FIG. 2A exhibits a very regular and uniform pattern that follows the subjacent pattern, but with resolution at 4 times the subjacent pattern resolution. The pattern resolution evident in FIG. 2A is about 29 nm.

FIG. 2B is a micrograph of a substrate processed according to another embodiment of the method 100. To make the substrate of FIG. 2B, a patterned substrate was coated with a self-aligning material, dried, heated to 340° C., and cooled at a controlled rate of 5° C./sec. The substrate of FIG. 2B shows micron-sized areas with complete uniformity of the pattern and registration with the underlying pattern at resolution of 4 times the subjacent pattern resolution, but with some regions lacking pattern registration. The pattern resolution evident in FIG. 2B is about 28 nm.

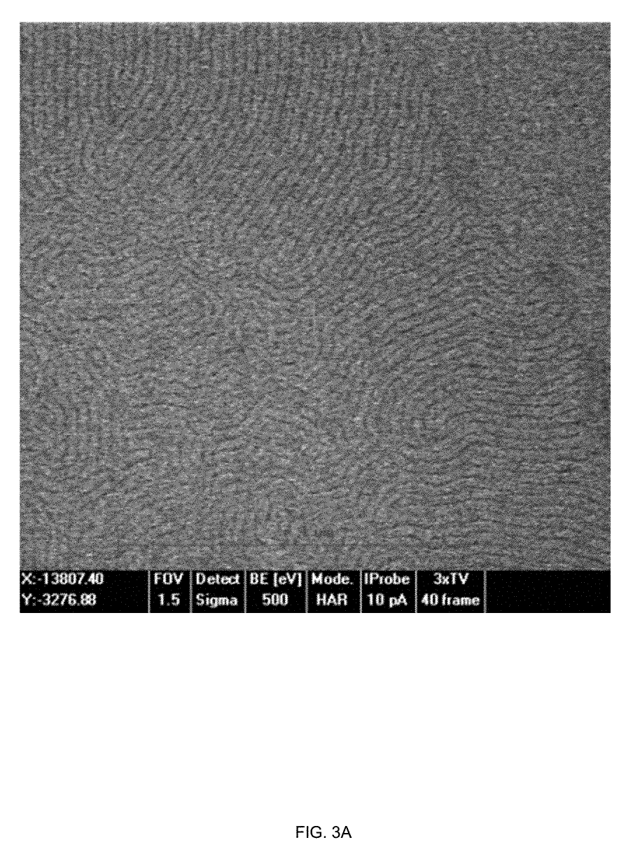

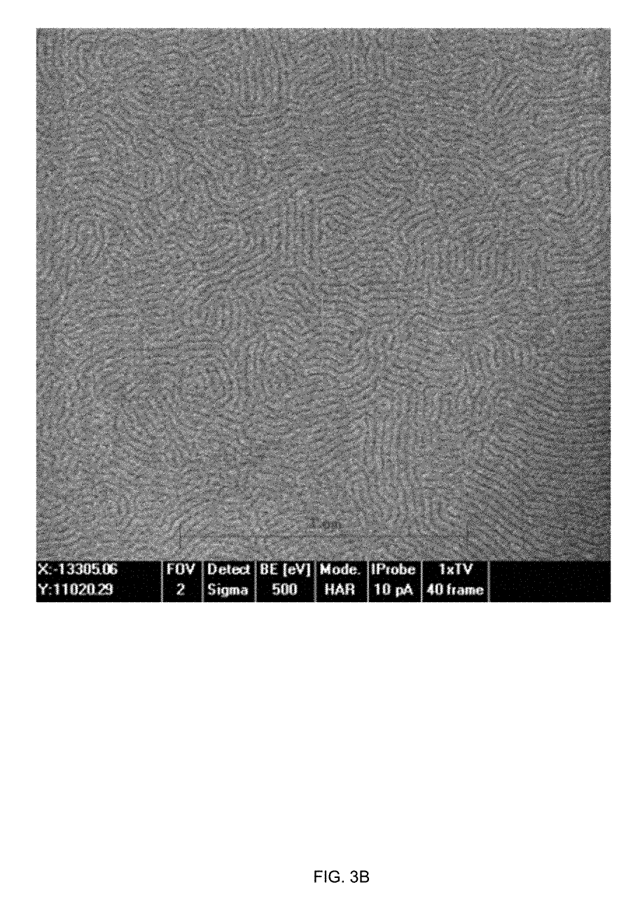

FIG. 3A is a micrograph of a substrate processed according to a comparative method. The substrate of FIG. 3A was subjected to a spike anneal at 350° C. with total duration of thermal treatment 32 seconds.

Although the pattern shows regular spacing, there is no registration with the underlying pattern.

FIG. 3B is a micrograph of a substrate processed according to another comparative method. The substrate of FIG. 3B was subjected to a spike anneal of 350° C. spike treatment of duration 13.3 seconds followed by a 2 minute soak at 325° C. Similar to the substrate of FIG. 3A, the substrate of FIG. 3B exhibits regular pattern spacing, but no registration with the underlying pattern. Each of the substrates of FIGS. 2A, 2B, 3A, and 3B used PS-b-PMMA as the self-aligning material.

The methods disclosed herein describe a thermal treatment for substrates having self-assembling materials deposited thereon that can achieve directed self-assembly of such materials in 10 minutes or less of processing time, yielding 4× pattern resolution.

While the foregoing is directed to certain embodiments, other and further embodiments may be devised without departing from the basic scope of this disclosure.

What is claimed is:

1. A method of processing a semiconductor substrate, comprising:
heating a semiconductor substrate having a directed self-assembling material disposed thereon to a target temperature between about 325° C. and about 380° C.; and
cooling the substrate to a temperature of 100° C. at a rate less than about 5° C./sec.

2. The method of claim 1, wherein the cooling is performed at a rate of 1° C./sec or less.

3. The method of claim 1, wherein the target temperature is between about 330° C. and about 350° C., and the cooling rate is 1° C./sec or less.

4. The method of claim 1, wherein the target temperature is between a glass transition temperature of the directed self-assembling material and a decomposition temperature of the directed self-assembling material.

5. The method of claim 4, wherein the target temperature is between a first temperature at which the directed self-assembling material exhibits a transition from an ordered structure to a disordered structure and the decomposition temperature.

6. The method of claim 5, wherein the target temperature is above a midpoint between the first temperature and the decomposition temperature.

7. A method of patterning a substrate, comprising:
providing a substrate having a directed self-assembling material disposed thereon to an RTP chamber;
heating the substrate at a rate of 5° C./sec or more to a target temperature of 325° C. to 380° C.; and
cooling the substrate to a temperature of 100° C. at a controlled rate less than 5° C./sec.

8. The method of claim 7, wherein the cooling is performed at a rate of 1° C./sec or less.

9. The method of claim 7, wherein the target temperature is between about 330° C. and about 350° C., and the cooling rate is 1° C./sec or less.

10. The method of claim 7, wherein the target temperature is between a glass transition temperature of the directed self-assembling material and a decomposition temperature of the directed self-assembling material.

11. The method of claim 10, wherein the target temperature is between a first temperature at which the directed self-assembling material exhibits a transition from an ordered structure to a disordered structure and the decomposition temperature.

12. The method of claim 11, wherein the target temperature is above a midpoint between the first temperature and the decomposition temperature.

13. The method of claim 12, wherein the directed self-assembling material is a polystyrene-polymethylmethacrylate material.

14. A method of processing a substrate, comprising:
forming a directed self-assembling material on a patterned substrate;
at least partially drying the directed self-assembling material;
heating the substrate in a uniform radiant energy field at a rate of 5° C./sec or more to a target temperature above the glass transition temperature of the directed self-assembling material; and
cooling the substrate at a controlled rate of 1° C./sec or less to a temperature of 100° C.

15. The method of claim 14, wherein the directed self-assembling material is a polyolefin-polyacrylate copolymer.

16. The method of claim 14, wherein the target temperature is between a glass transition temperature of the directed self-assembling material and a decomposition temperature of the directed self-assembling material.

17. The method of claim 16, wherein the target temperature is between a first temperature at which the directed self-assembling material exhibits a transition from an ordered structure to a disordered structure and the decomposition temperature.

18. The method of claim 17, wherein the directed self-assembling material is a polystyrene-polymethylmethacrylate material.

19. The method of claim 18, wherein the method is performed in a radiant energy chamber that exposes the substrate to a uniform radiant energy field.

20. The method of claim 19, further comprising rotating the substrate during the heating and during the cooling.
